(19) United States
(12) Patent Application Publication
(10) Pub. No.: US 2006/0175652 A1
(43) Pub. Date: Aug. 10, 2006

(54) NON-VOLATILE MEMORY AND OPERATING METHOD THEREOF

(76) Inventors: Ching-Sung Yang, Hsinchu City (TW); Wei-Zhe Wong, Tainan City (TW); Chih-Chen Cho, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,362

(22) Filed: Aug. 1, 2005

(30) Foreign Application Priority Data
Feb. 4, 2005 (TW) 94103558

(51) Int. Cl. H01L 29/76

(52) U.S. Cl. 257/314

(57) ABSTRACT

A non-volatile memory having memory cell columns is provided. Each memory cell column includes many memory cells having a charge-trapping layer and a column select unit. There are no gaps between the memory cells and between the column select unit and the memory cells. A source region and a drain region are disposed in the substrate next to the sides of the serially connected memory cells and column select unit. The selecting lines connect to the gates of the column select unit in the same row. The word lines connect to the gates of the memory cells in the same row. The source lines connect to the source regions in the same row. The sub-bit lines connect to the drain regions in the same column. The main-bit lines connect to the sub-bit lines respectively. The sub-bit line select units are disposed between the sub-bit lines and the main bit lines.

### CROSS-REFERENCE TO RELATED APPLICATION

This application claims the priority benefit of Taiwan application serial no. 94103558, filed on Feb. 4, 2005. All disclosure of the Taiwan application is incorporated herein by reference.

### BACKGROUND OF THE INVENTION

1. Field of the Invention

The present invention relates to a semiconductor device. More particularly, the present invention relates to a non-volatile memory and an operating method thereof.

2. Description of the Related Art

Among the various types of non-volatile memory products, electrically erasable programmable read only memory (EEPROM) is a memory device that has been widely used inside personal computer systems and electronic equipment. In an EEPROM, data can be stored, read out or erased numerous times and any stored data is retained even after power is cut off.

Typically, the floating gate and the control gate of an EEPROM cell are fabricated using doped polysilicon. To prevent errors in reading data from an EEPROM due to over-erasing, an additional select gate is disposed on the sidewall of the control gate and the floating gate above the substrate to form a split-gate structure.

In the conventional technique, a charge-trapping layer sometimes replaces the polysilicon floating gate. The charge-trapping layer is fabricated using silicon nitride, for example. In general, an oxide layer is formed both above and below the silicon nitride charge-trapping layer respectively to form a stacked structure including an oxide-nitride-oxide (ONO) composite layer. This type of memory is often referred to as a silicon-oxide-nitride-oxide-silicon (SONOS) memory device. A SONOS device having a split-gate structure has been disclosed, for example, in U.S. Pat. No. 5,930,631.

However, the aforementioned SONOS device with split-gate structures needs to have a larger area to accommodate the split-gate structures. With increased dimension of each memory cell, the SONOS memory occupies an area larger than the conventional EEPROM with stacked gate structures and hence has a lower level of integration.

### SUMMARY OF THE INVENTION

Accordingly, at least one objective of the present invention is to provide a non-volatile memory and an operating method thereof, capable of increasing the degree of integration of memory cells and enhance device performance.

At least a second objective is to provide a non-volatile memory and an operating method thereof that utilizes source-side injection to perform a programming operation to increase programming speed and improve memory efficiency.

At least a third objective of the present invention is to provide a non-volatile memory and an operating method thereof capable of stabilizing memory cell programming and reading operation and improve programming performance.

To achieve these and other advantages and in accordance with the purpose of the invention, as embodied and broadly described herein, the invention provides a non-volatile memory. The non-volatile memory mainly includes a substrate, a main-bit line, a sub-bit line select unit, a sub-bit line, a plurality of word lines, a column select unit, a first doped region, and a second doped region. The main-bit line is disposed on the substrate. The sub-bit line connects with the main-bit line through the sub-bit line select unit. The word lines are arranged in parallel to one another in a direction perpendicular to the sub-bit line. The crossing points between the word lines and the sub-bit line corresponds to a memory cell column. The column select unit is disposed on the outer side of the memory cell column. The first doped region is disposed in the substrate on the outer side of the column select unit. The memory cell column connects to the sub-bit line through the first doped region. The second doped region is disposed in the substrate on the other side of the memory cell column. The memory cell column includes a plurality of first memory cells and a plurality of second memory cells. The first memory cells are separated from the column select unit by a gap. Each second memory cell is disposed inside the gap. The second memory cells are serially connected to the first memory cells and the column select unit through a plurality of insulating spacers.

In the aforementioned non-volatile memory, each first memory cell includes a first gate and a first composite layer. The first gate is disposed on the substrate. The first composite layer is disposed between the first gate and the substrate. Furthermore, the first composite layer includes a first bottom dielectric layer, a first charge-trapping layer and a first top dielectric layer sequentially formed over the substrate. Each second memory cell includes a second gate and a second composite layer. The second gate is disposed on the substrate. The second composite layer is disposed between the second gate and the substrate and between the second gate and the first memory cell. Furthermore, the second composite layer includes a second bottom dielectric layer, a second charge-trapping layer, and a second top dielectric layer sequentially formed over the substrate and the sidewall on one side of the first memory cell. The column select unit includes a third gate and a third composite layer. The third gate is disposed on the substrate. The third composite layer is disposed between the third gate and the substrate. Furthermore, the third composite layer includes a third bottom dielectric layer, a third charge-trapping layer, and a third top dielectric layer sequentially formed over the substrate. The sub-bit line select unit includes a fourth gate, a gate dielectric layer, and a pair of doped regions (a third doped region and a fourth doped region). The fourth gate is disposed on the substrate. The gate dielectric layer is disposed between the fourth gate and the substrate. The third doped region and the fourth doped region are disposed in the substrate on the sides of the fourth gate, respectively. The third doped region connects with the main-bit line, and the fourth doped region connects with the sub-bit line.

In the aforementioned non-volatile memory, the first charge-trapping layer, the second charge-trapping layer, and the third charge-trapping layer can be fabricated using silicon nitride or doped polysilicon. The first bottom dielectric layer, the first top dielectric layer, the second bottom dielectric layer, the second top dielectric layer, the third bottom dielectric layer, the third top dielectric layer, and the gate dielectric layer can be fabricated using silicon oxide. The first gate, the second gate, the third gate, and the fourth gate can be fabricated using doped polysilicon. The method of forming the first insulating spacers includes depositing an insulating material over the first gate and performing a self-aligned anisotropic etching operation, for example.

In the present invention, a sub-bit line select unit is deposited between the main-bit line and the sub-bit line. The sub-bit line select unit can control the amount of current flowing from the main-bit line to the sub-bit line. In other words, the sub-bit line select unit provides a current-controlling function. Hence, a better programming performance can be achieved when operating the non-volatile memory of the present invention.

The present invention also provides an alternative non-volatile memory. The non-volatile memory mainly includes a substrate, a plurality of memory cell columns, a plurality of column select units, a plurality of source regions, a plurality of drain regions, a plurality of selecting lines, a plurality of word lines, a plurality of source lines, a plurality of sub-bit lines, a plurality of main-bit lines, and a plurality of sub-bit line select units. The memory cells are disposed on the substrate and arranged to form a column/row array. Each memory cell column includes a plurality of memory cells serially connected but isolated from each other by a first insulating spacer. The column select units are disposed on one side of each memory cell column through a second insulating spacer respectively. The source regions are disposed in the substrate on the other side of each memory cell column. The drain regions are disposed in the substrate on the outer side of each column select unit. Each pair of neighboring memory cell columns in the same column shares a common drain region. The selecting lines connect the gate of the column select units in the same row. The word lines are arranged in parallel in the row direction and connect to the gates of the memory cells in the same row. The sub-bit lines connect the drain regions in the same column. Each sub-bit line serially connects N memory cell columns in the column direction, where N is a positive integer. The main-bit lines are arranged in parallel to one another in the column direction. Each main-bit line connects M sub-bit lines, where M is a positive integer. Each main-bit line can serially connect N×M memory cell columns. The sub-bit line select units are disposed between various sub-bit lines and the main-bit lines.

In the aforementioned non-volatile memory, among the plurality of memory cells in the same memory cell column, every two memory cells from the source region constitute a memory cell unit. The memory cell of each memory unit which is close to the source region is a first memory cell and the memory cell of each memory unit which is close to the drain region is a second memory cell. The first memory cell includes a first gate and a first composite layer. The first gate is disposed on the substrate. The first composite layer is disposed between the first gate and the substrate. Furthermore, the first composite layer includes a first bottom dielectric layer, a first charge-trapping layer, and a first top dielectric layer, sequentially formed over the substrate. The second memory cell includes a second gate and a second composite layer. The second gate is disposed on the substrate. The second composite layer is disposed between the second gate and the substrate and between the second gate and the first memory cell. Furthermore, the second composite layer includes a second bottom dielectric layer, a second charge-trapping layer, and a second top dielectric layer, sequentially formed over the substrate and a sidewall on one side of the first memory cell. The first insulating spacers are disposed on the sidewall of the first memory cell.

In the aforementioned non-volatile memory, the first charge-trapping layer and the second charge-trapping layer can be fabricated using silicon nitride or doped polysilicon. The first bottom dielectric layer, the first top dielectric layer, the second bottom dielectric layer, and the second top dielectric layer can be fabricated using silicon oxide.

In the aforementioned non-volatile memory, each column select unit includes a third gate, a third composite layer, and a third insulating spacer. The third gate is disposed on the substrate. The third composite layer is disposed between the third gate and the substrate. Furthermore, the third composite layer includes a third bottom dielectric layer, a third charge-trapping layer, and a third top dielectric layer sequentially formed on the substrate. The third insulating spacers are disposed on the third gate and the sidewall of the third composite layer.

In the aforementioned non-volatile memory, the third charge-trapping layer can be fabricated using silicon nitride. The third bottom dielectric layer and the third top dielectric layer can be fabricated using silicon oxide.

In the non-volatile memory of the present invention, the memory cell column is constructed using a plurality of memory cells and a column select unit. Because there are no gaps between various memory cells and there are no gaps between the column select unit and the memory cells, the overall level of integration of the memory cell array can be increased.

Furthermore, in the non-volatile memory of the present invention, main-bit lines are also deposited. The main-bit lines can connect with more than four (more than two columns) sub-bit lines. Therefore, the main-bit lines can have twice the width so that the processing window is increased.

In addition, the memory cell utilizes the charge-trapping layer as a charge storage unit. Hence, there is no need to consider a gate-coupling ratio. Ultimately, the operating voltage can be reduced and the operating efficiency of the memory cell can be increased. Moreover, each memory cell in the memory cell column can store electric charges. Hence, overall storage capacity is significantly increased.

The present invention also provides a method of operating a non-volatile memory. The method includes performing a programming operation. To initiate the programming operation, 0V is applied to the selected main-bit line; a first voltage is applied to the non-selected main-bit lines; a second voltage is applied to the gate of the sub-bit line select unit coupled to the selected memory cell in the memory cell column; a third voltage is applied to the selected word line which is adjacent to the word line coupled to the selected memory cell on the drain region; a fourth voltage is applied to the other non-selected word lines and selecting lines; and a fifth voltage is applied to a selected source line so that source-side injection is utilized to program data into the selected memory cell.

In the aforementioned method of operating the non-volatile memory, the first voltage is about 3.3V, the second voltage is about 1.5V, the third voltage is about 1.5V, the fourth voltage is about 9V, and the fifth voltage is about 4.5V.

In the aforementioned method of operating the non-volatile memory, before the second voltage is applied to the gate of the sub-bit line select unit, a sixth voltage is applied to gate of the sub-bit line select unit. The sixth voltage is about 6V.

In the aforementioned method of operating the non-volatile memory, the step of applying the third voltage to the selected word line further includes ramping up the third voltage gradually from about 0V to 1.5V.

In the aforementioned method of operating the non-volatile memory, before the step of applying the third voltage to the selected word line, further includes applying a seventh voltage, which is lower than the third voltage, to the selected word line first and then ramping up to the third voltage. The seventh voltage is about 0.1V. Furthermore, a program verification step is performed after each ramping up stage.

In the aforementioned method of operating the non-volatile memory, the memory cells are programmed sequentially from the source region side to drain region side.

The aforementioned method of operating the non-volatile memory further includes performing a reading operation. To initiate the reading operation, 0V is applied to the selected main-bit line, and an eighth voltage is applied to the non-selected main-bit lines; a ninth voltage is applied to the gate of the sub-bit line select unit coupled to the memory cell column containing the selected memory cell; a tenth voltage is applied to the word line coupled to the selected memory cell, and an eleventh voltage is applied to other non-selected word lines and selected selecting lines; and a twelfth voltage is applied to the source line to read out data from the selected memory cell.

In the aforementioned method of operating the non-volatile memory, the eighth voltage is about 1.5V, the ninth voltage is about 3.3V, the tenth voltage is about 1.5V, the eleventh voltage is about 6V, and the twelfth voltage is about 1.5V.

In the aforementioned method of operating the non-volatile memory, the memory cells are read sequentially from the source region side to drain region side.

The aforementioned method of operating the non-volatile memory further includes performing an erasing operation. To initiate the erasing operation, a thirteenth voltage is applied to the selected main-bit line and 0V is applied to the non-selected main-bit lines; a fourteenth voltage is applied to the gate of the sub-bit line select unit coupled to the memory cell column containing the selected memory cell; a fifteenth voltage is applied to the word line of the selected memory cell, and a sixteenth voltage is applied to all the non-selected word lines and selected selecting lines between the word line coupled to the selected memory cell and the drain region; and 0V is applied to all the non-selected word lines disposed between the word line coupled to the selected memory cell and the source region so that hot-hole injection is triggered to erase the data in the selected memory cell.

In the aforementioned method of operating the non-volatile memory, the thirteenth voltage is about 4.5V, the fourteenth voltage is about 3.3V, the fifteenth voltage is about −5V and the sixteenth voltage is about 9V.

In the aforementioned method of operating the non-volatile memory, the seventeenth voltage is applied to the word lines and a eighteenth voltage is applied to the substrate so that FN tunneling is triggered to erase data from the entire memory during the erasing operation.

In the aforementioned method of operating the non-volatile memory, the seventeenth voltage is about −12V and the eighteenth voltage is about 0V.

In the aforementioned method of operating the non-volatile memory, the seventeenth voltage is about 0V and the eighteenth voltage is about 12V.

In the aforementioned method of operating the non-volatile memory, the seventeenth voltage is about −6V and the eighteenth voltage is about 6V.

In the programming method of the present invention, the memory cells in the memory cell column are programmed sequentially from the source region end. Hence, programming interference due to the retention of some electrons within the charge-trapping layer can be prevented. Hence, a higher programming performance can be achieved.

Furthermore, sub-bit line select units are disposed between the main-bit lines and the sub-bit lines. Since the sub-bit line select unit can control the amount of current flowing from the main-bit line to the sub-bit line, the sub-bit line select unit has a current-limiting function. Thus, better programming performance can be reached.

In the programming method of the present invention, the step of applying 1.5V to the selected word line adjacent to the word line coupled to the selected memory cell and close to the drain region further includes raising the voltage gradually so that the programming efficiency is improved. Furthermore, a program verification process is performed at each increase of the voltage.

In the reading method of the present invention, the data from various memory cells of a memory cell column are read sequentially from the source region end of the memory cell column.

In the operating method of the present invention, source-side injection (SSI) is used to program data into the memory with a single bit of data in a single memory cell serving as a basic unit. Either hot-hole injection or F-N tunneling is used to erase data from the memory cells. Since the electron injection efficiency is high, the operating memory cell current is reduced and the operating speed is increased. Thus, current consumption is minimized and the power loss from the entire chip is effectively reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a non-volatile memory according to one embodiment of the present invention.

FIG. 1B is a cross-sectional view showing the structure along line A-A′ of FIG. 1A.

FIG. 1C is a cross-sectional view showing the structure of a memory unit and a column select unit according to an embodiment of the present invention.

FIG. 2 is a simplified circuit diagram showing the operating mode of a non-volatile memory according to an embodiment of the present invention.

FIG. 3A is a diagram showing a programming operation according to one embodiment of the present invention.

FIG. 3B is a diagram showing a reading operation according to one embodiment of the present invention.

FIG. 3C is a diagram showing an erasing operation according to one embodiment of the present invention.

FIG. 3D is a diagram showing another erasing operation according to one embodiment of the present invention.

FIG. 3E is a diagram showing still another erasing operation according to one embodiment of the present invention.

FIG. 3F is a diagram showing yet another erasing operation according to one embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

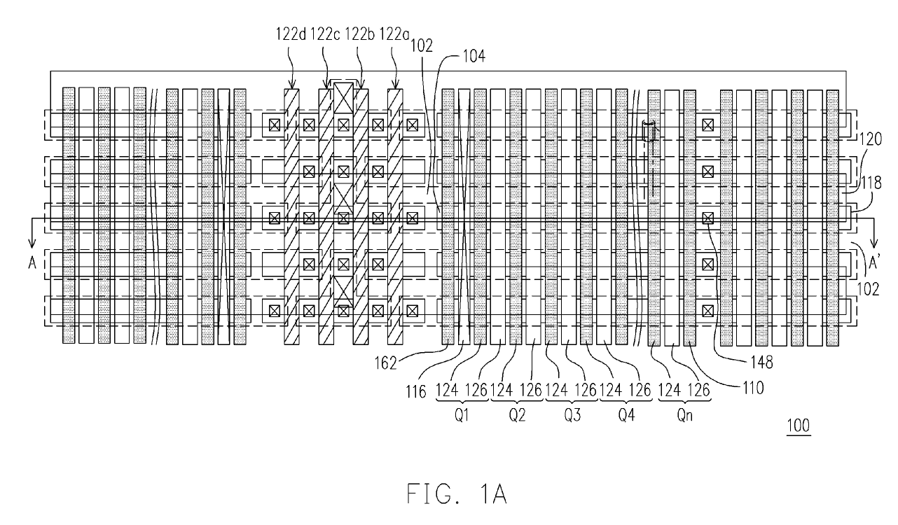

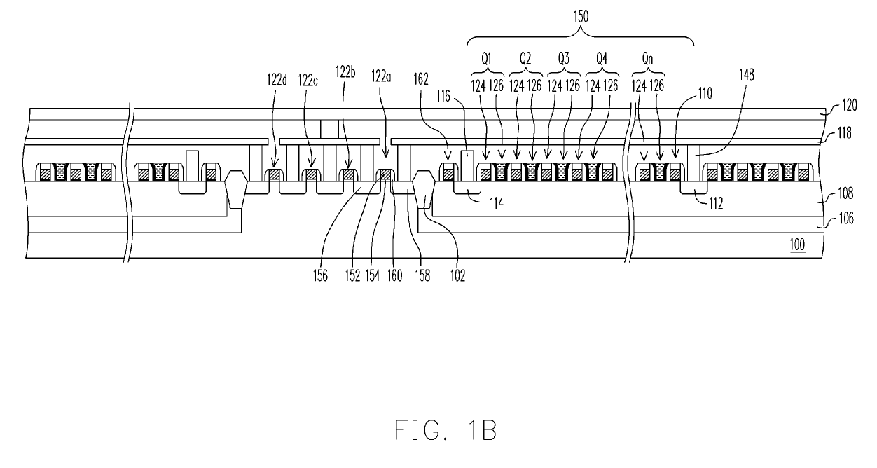

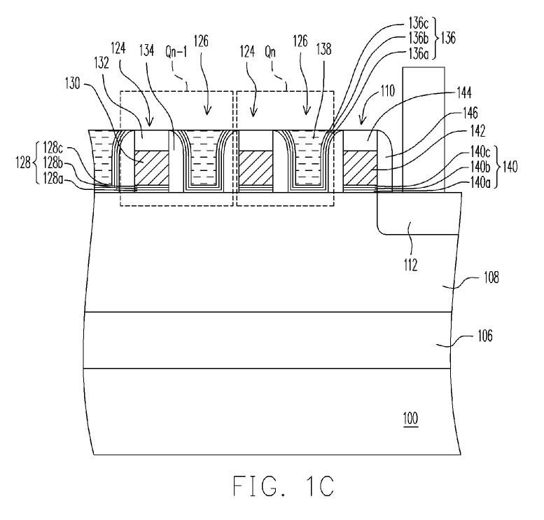

FIG. 1A is a top view of a non-volatile memory according to one embodiment of the present invention. FIG. 1B is a cross-sectional view showing the structure along line A-A′ of FIG. 1A. FIG. 1C is a cross-sectional view showing the structure of a memory unit and a column select unit according to an embodiment of the present invention.

As shown in FIGS. 1A, 1B and 1C, the non-volatile memory of the present invention mainly includes a substrate 100, a device isolation structure 102, an active region 104, a deep N-type well 106, a P-type well 108, a plurality of memory units Q1˜Qn, a column select unit 110, a drain region 112, a source region 114, a source line 116, a sub-bit line 118, a main-bit line 120, and a plurality of sub-bit line select units 122a·122d.

The substrate 100 is a silicon substrate, for example. The substrate 100 can be a P-type substrate. The device isolation structure 102 is disposed in the substrate 100 for defining the active region 104. The deep N-type well 106 is disposed in the substrate 100. The P-type well 108 is disposed within the deep N-type well 106. The device isolation structure 102 can isolate the neighboring P-type wells 108 so as to prevent charging the entire substrate 100 during operation (i.e., erasure operation) and thus save the power.

The plurality of memory units Q1˜Qn are disposed on the substrate 100. Each of the memory units Q1˜Qn includes a first memory cell 124 and a second memory cell 126.

The first memory cell 124 is disposed on the substrate 100. The first memory cell 124 includes a composite layer 128, a gate 130, a cap layer 132, and a pair of insulating spacers 134. The gate is disposed on the substrate 100. The composite layer 128 is disposed between the gate 130 and the substrate 100. Furthermore, the composite layer 128 includes a bottom dielectric layer 128a, a charge-trapping layer 128b, and a top dielectric layer 128c, sequentially stacked over the substrate 100. The cap layer 132 is disposed on the gate 130. The insulating spacers 134 are disposed on the sidewalls of the gate 130 and the composite layer 128, respectively. The insulating spacers 134 are formed, for example, by depositing an insulating layer over the gate 130 and then performing a self-aligned anisotropic etching operation. The bottom dielectric layer 128a is fabricated using silicon oxide, the charge-trapping layer 128b is fabricated using silicon nitride, the top dielectric layer 128c is fabricated using silicon oxide and the gate 130 is fabricated using doped polysilicon, for example. The cap layer 132 is fabricated using silicon oxide and the insulating spacers 134 are fabricated using an insulating material such as silicon nitride or silicon oxide.

The second memory cell 126 is disposed on one side of the first memory cell 124 and the substrate 100. The second memory cell 126 includes a composite layer 136 and a gate 138. The gate 138 is disposed on the substrate 100, and the composite layer 136 is disposed between the gate 138 and the substrate 100, for example. As shown in FIG. 1 C, the composite layer 136 has a U-shaped structure formed between the two gate structures. The composite layer 136 includes a bottom dielectric layer 136a, a charge-trapping layer 136b, and a top dielectric layer 136c, sequentially stacked on the substrate 100. The bottom dielectric layer 136a is fabricated using silicon oxide, the charge-trapping layer 136b is fabricated using silicon nitride, the top dielectric layer 136c is fabricated using silicon oxide, and the gate 138 is fabricated using doped polysilicon, for example. The second memory cell 126 is isolated from the first memory cell 124 through the insulating spacer 134.

The memory units Q1˜Qn are serially connected on the active region 104 without any gaps in between, for example. In each of the memory units Q1˜Qn, the first memory cell 124 is isolated from the second memory cell 126 through the insulation spacer 134.

Although a silicon nitride charge-trapping layer is used in the present embodiment, the structure in the present invention can be applied to a floating gate flash memory as well. The floating gate flash memory structure has doped polysilicon charge-trapping layers 128b and 136b, for example.

The column select unit 110 is connected to the outermost memory cell 126 in the serially connected memory units Q1˜Qn. The column select unit 110 includes a composite layer 140, a gate 142, a cap layer 144, and a pair of insulating spacers 146, for example. The gate 142 is disposed on the substrate 100. The composite layer 140 is disposed between the gate 142 and the substrate 100. Furthermore, the composite layer includes a bottom dielectric layer 140a, a charge-trapping layer 140b, and a top dielectric layer 140c, sequentially stacked on the substrate 100. The cap layer 144 is disposed on the gate 142. The insulating spacers 146 are disposed on the sidewalls of the gate 142 and the composite layer 140 respectively. The bottom dielectric layer 140a is fabricated using silicon oxide, the charge-trapping layer 140b is fabricated using silicon nitride, the top dielectric layer 140c is fabricated using silicon oxide, and the gate 142 is fabricated using doped polysilicon, for example. The cap layer 144 is fabricated using silicon oxide, and the insulating spacers 146 are fabricated using silicon nitride or silicon oxide, for example. The column select unit 110 is isolated from the outermost memory cell 124 of the serially connected memory units Q1˜Qn through the insulating spacer 146.

The drain region 112 is disposed in the substrate 100 on the outer side of the column select unit 110, not adjacent to the serially connected memory unit Q1˜Qn. The source region 114 is disposed on the other side of the serially connected memory unit Q1˜Qn corresponding to the drain region 112. In other words, the substrate 100 is outside the outermost memory cell 124 of the serially connected memory units Q1˜Qn.

In addition, the drain region 112 is connected to the sub-bit line 118 through an conductive plug 148. The source region 114 is electrically connected to the source line 116. The serially connected memory units Q1˜Qn, the column select unit 110, the drain region 112, and the source region 114 together form a memory cell column 150. Furthermore, every pair of adjacent memory cell columns 150 in a same column share a common drain region 112.

The sub-bit lines 118 connect the drain regions 112 in the same column. Each sub-bit line 118 serially connects N memory cell columns 150 in the column direction, where N is a positive integer.

The plurality of main-bit lines 120 are arranged in parallel with one another in the column direction. Each main-bit line 120 can connect M sub-bit lines 118 parallel-arranged in the column direction, where M is a positive integer. For example, one main-bit line can connect with 4, 6, 8, 10, or more than 10 sub-bit lines 118. Hence, each main-bit line 120 can connect with N×M memory cell columns 150 altogether.

The plurality of sub-bit line select units 122a˜122d are disposed between the sub-bit lines 118 and the main-bit lines 120. The sub-bit line select unit 122a includes a gate 152, a gate dielectric layer 154, a doped region 156, a doped region 158, and spacers 160, for example. The sub-bit line select units 122a˜122d each connects with a different sub-bit line 118 and a main-bit line 120 for controlling the conduction between different sub-bit line 118 and the main-bit line 120. Each pairs of adjacent bit-line select units 122a˜122d share a common doped region.

The gate 152 is disposed on the substrate 100. The gate dielectric layer 154 is disposed between the gate 152 and the substrate 100. The gate dielectric layer 154 is fabricated using silicon oxide, for example. The doped region 156 and the doped region 158 are disposed in the substrate 100 on each side of the gate 152, and the spacers 160 are disposed on the sidewalls of the gate 152, for example. The spacers 160 are fabricated using silicon nitride or silicon oxide, for example. The doped region 156 of the sub-bit line select unit 122 is connected to the main-bit line 120 through an conductive plug (not shown), and the doped region 158 is connected to the sub-bit line 118. The main-bit line 120 and the sub-bit line 118 are electrically connected when the sub-bit line select unit 122 is turned on. Furthermore, a dummy word line 162 is also disposed on one side of the source line 116 not adjacent to the memory cell row.

In the aforementioned non-volatile memory, the memory cell columns 150 on the active region 104 include a plurality of alternately positioned memory cell 124 and memory cell 126 and a column select unit 110. Because there are no gaps between the memory cell 124 and the memory cell 126 and there are no gaps between the column select unit 110 and the memory cell 126, the overall integration of the memory cell array is increased.

In the aforementioned non-volatile memory, each main-bit line 120 is capable of connecting with more than four (more than two columns) sub-bit lines 118. Therefore, the main-bit lines 120 can have twice width of normal bit lines so that the processing window is significantly increased.

In addition, the number of serially connected memory cell structures in the present invention is not limited. For example, a total from 32 to 64 memory cell structures can be serially connected to form a memory cell column 150.

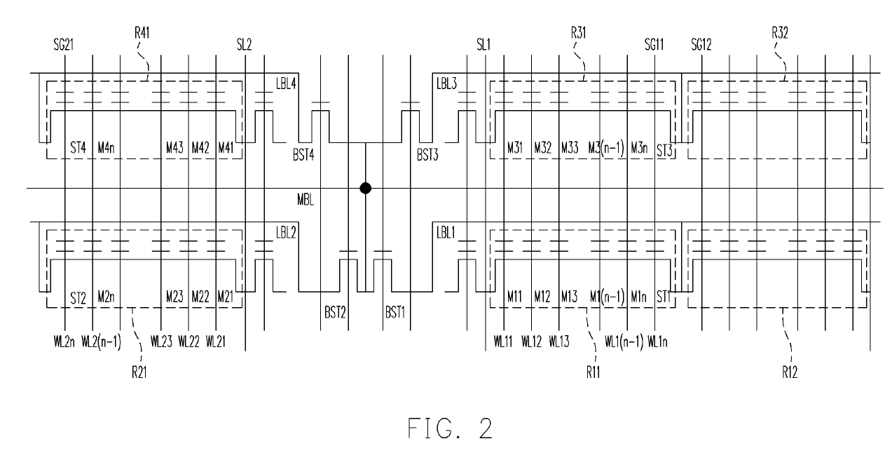

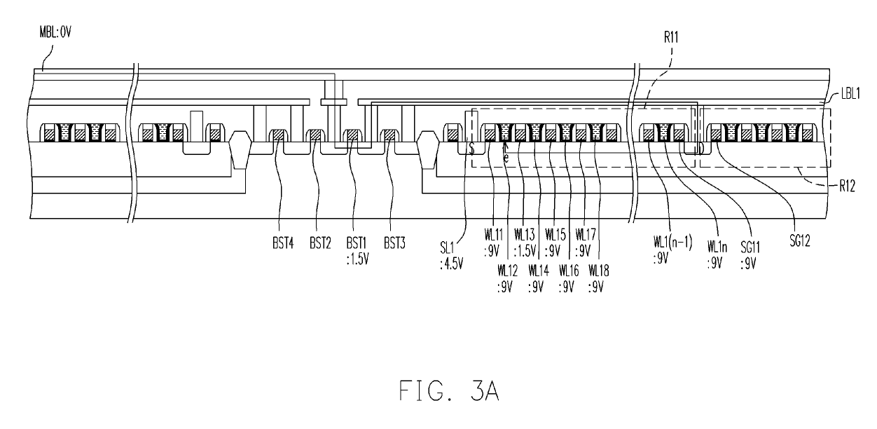

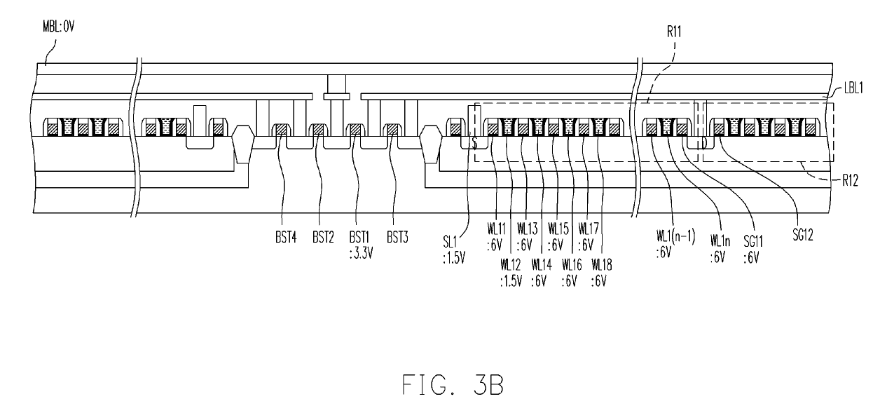

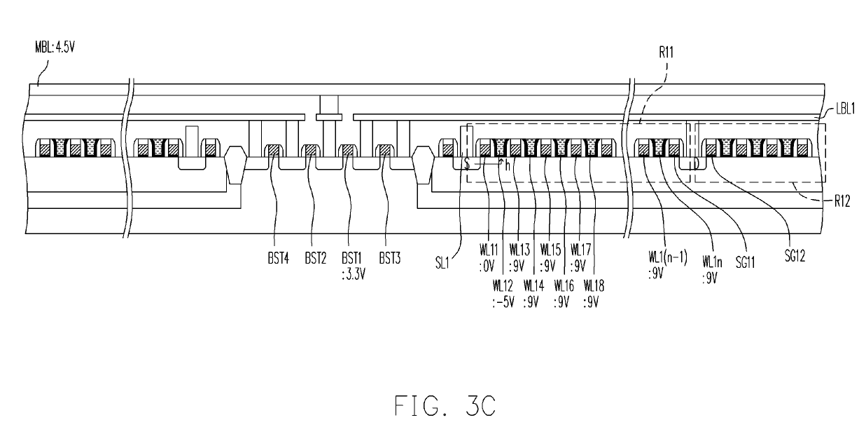

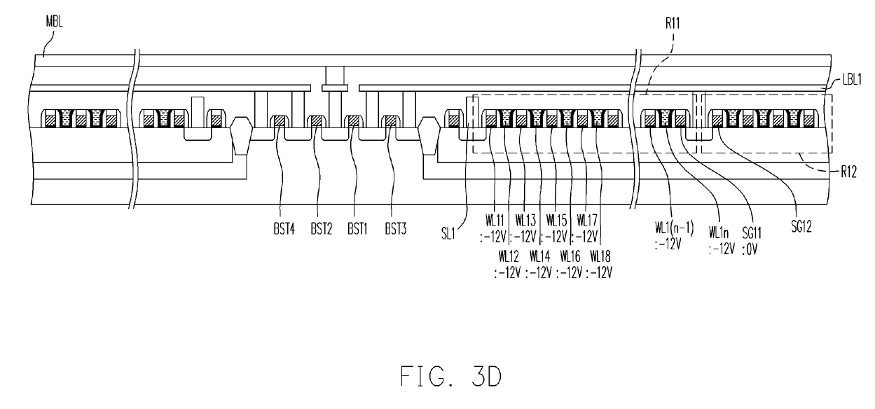

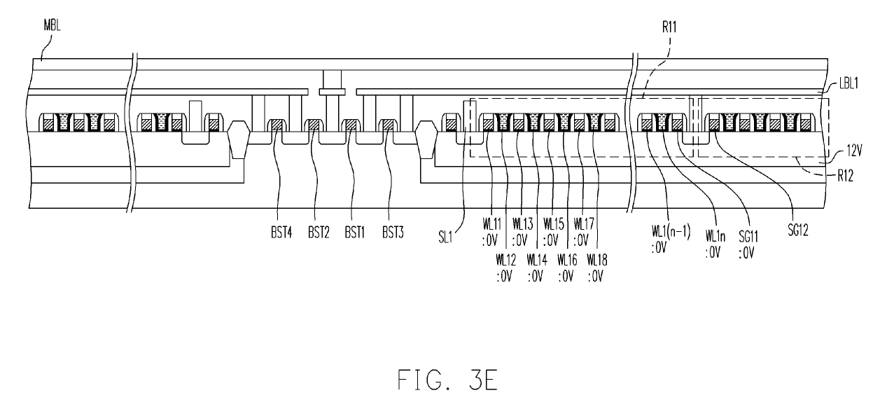

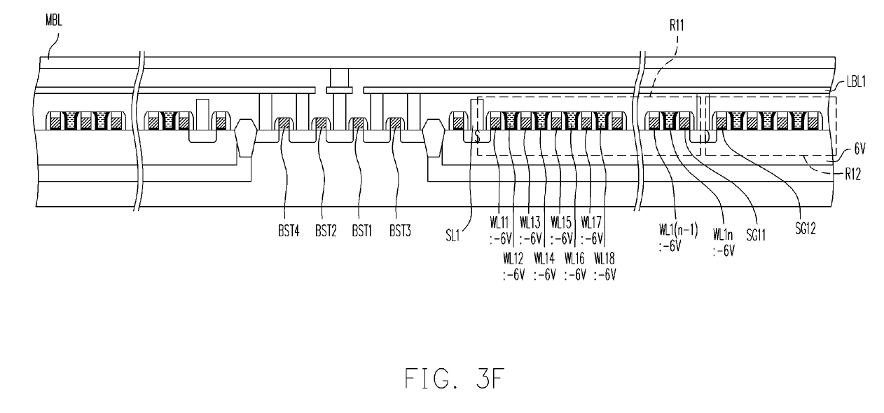

FIG. 2 is a simplified circuit diagram showing the operating mode of a non-volatile memory according to an embodiment of the present invention. FIG. 3A is a diagram showing a programming operation according to one embodiment of the present invention. FIG. 3B is a diagram showing a reading operation according to one embodiment of the present invention. FIG. 3C is a diagram showing an erasing operation according to one embodiment of the present invention. FIG. 3D is a diagram showing another erasing operation according to one embodiment of the present invention. FIG. 3E is a diagram showing still another erasing operation according to one embodiment of the present invention. FIG. 3E is a diagram showing yet another erasing operation according to one embodiment of the present invention.

As shown in FIG. 2, the non-volatile memory of the present invention includes a plurality of memory cell columns R11˜R41, a plurality of selecting lines SG11˜SG21, a plurality of word lines WL11˜WL2n, a plurality of sub-bit lines LBL1˜LBL4, a main-bit lines MBL, a plurality of sub-bit line select units BST1˜BST4 and a pair of source lines SL1 and SL2.

The memory cell columns R11˜R41 are disposed on the substrate and arranged to form a column/row array. The memory cells in each memory cell column are serially connected without any gaps in between. Furthermore, the column select units and the outermost memory cells are serially connected without any gaps. For example, the memory cells M11, M12, M13 . . . M1n and the column select units ST1 together constitute the memory cell column R11; the memory cells M21, M22, M13 . . . M2n and the column select unit ST2 together constitute the memory cell column R21; the memory cells M31, M32, M33 . . . M3n and the column select units ST3 together constitute the memory cell column R31; and, the memory cells M41, M42, M43 . . . M4n and the column select unit ST4 together constitute the memory cell column R41. Similarly, the memory cell columns R12 and R32 are also formed by serially connecting n memory cells and a column select unit together. For a simple explanation, a detailed description of the memory cell columns R12 and R32 is omitted.

The selecting lines SG11, SG12, SG21 are arranged in parallel in the row direction to connect with the gate of the column select units in the same row. For example, the selecting line SG11 is connected to the gate of the column select units ST1 and ST3, and the selecting line SG21 is connected to the gate of the column select units ST2 and ST4.

The word lines WL11˜WL2n are arranged in parallel in the row direction to connect with the gate of the memory cells in the same row. For example, the word line WL11 is connected to the gate of the memory cells M11 and M31; the word line WL12 is connected to the gate of the memory cells M12 and M32; and, likewise, the word line WL1n is connected to the gate of the memory cells M1n and M3n. Similarly, the word line WL21 is connected to the gate of the memory cells M21 and M41; the word line WL22 is connected to the gate of the memory cells M22 and M42; and, likewise, the word line WL2n is connected to the gate of the memory cells M2n and M4n.

The source lines SL1 and SL2 connect with the source regions in the same row. The source regions are disposed in the substrate on another side of each memory cell column, for example, on one side of the memory cells M11, M21, M31, and M41. In each memory cell column, every pair of adjacent memory cells constitutes a memory unit. For example, the memory cells M11 and M12 constitute a memory unit; the memory cells M13 and M14 constitute a memory unit; and likewise, the memory cells M4(n−1) and M4n constitute a memory unit.

The plurality of sub-bit lines LBL1, LBL2, LBL3 and LBL4 are connected to the drain regions in the substrate on one side of the column select units ST1˜ST4 of the memory cell columns in the same column, respectively . Furthermore, in the same column, every pair of adjacent memory cell columns shares a common drain region. The cross points between the word lines WL11˜WL2n and the sub-bit lines LBL1˜LBL4 correspond to a plurality of memory cell columns. In addition, the sub-bit lines LBL1, LBL2, LBL3, and LBL4 serially connect with a plurality of memory cell columns in the column direction, respectively. For example, the sub-bit line LBL1 is serially connected to the memory cell columns R11 and R12; the sub-bit line LBL2 is serially connected to the memory cell column R21; the sub-bit line LBL3 is serially connected to the memory cell columns R31 and R32; and the sub-bit line LBL4 is serially connected to the memory cell column R41.

The plurality of main-bit lines MBL are arranged in parallel in the column direction. Each main-bit line MBL connects with a plurality of sub-bit lines. For example, the main bit line MBL connects with the sub-bit lines LBL1, LBL2, LBL3 and LBL4.

The plurality of sub-bit line select unit BST1 BST4 are disposed between each sub-bit lines LBL1, LBL2, LBL3 and LBL4 and the main-bit line MBL respectively for controlling the conduction between the main-bit line MBL and the sub-bit lines LBL1, LBL2, LBL3, and LBL4. For example, the bit line select unit BST1 is disposed between the main-bit line MBL and the sub-bit line LBL1 for controlling the conduction between the main-bit line MBL and the sub-bit line LBL1. The bit-line select unit BST2 is disposed between the main-bit line MBL and the sub-bit line LBL2 for controlling the conduction between the main-bit line MBL and the sub-bit line LBL2. The bit line select unit BST3 is disposed between the main-bit line MBL and the sub-bit line LBL3 for controlling the conduction between the main-bit line MBL and the sub-bit line LBL3 for controlling the conduction between the main-bit line MBL and the sub-bit line LBL3. The bit line select unit BST4 is disposed between the main-bit line MBL and the sub-bit line LBL4 for controlling the conduction between the main-bit line MBL and the sub-bit line LBL4.

As shown in FIGS. 2 and 3A, to program data into the memory cell M12, for example, 0V is applied to the selected main-bit line MBL and 3.3V is applied to the non-selected main-bit line; 1.5V is applied to the gate of the sub-bit line select unit BST1 coupled to the memory cell column R11 containing the selected memory cell M12 for connecting the main-bit line MBL and the sub-bit line LBL1 together; 1.5V is applied to the selected word line WL13, which is adjacent to the word line WL12 coupled to the selected memory cell M12 on the drain region D side, and 9V is applied to the other non-selected word lines WL11˜WL12, WL14˜WLn and the selected selecting line SG11; and 4.5V is applied to the source line SL1 to initiate source-side injection (SSI) so that electrons are injected into the charge-trapping layer of the memory cell M12 to program the selected memory cell M12. The electrons injected into the charge-trapping layer of the memory cell M12 are located in a region close to the drain region D.

In the aforementioned programming method, no voltage is applied to the selecting line SG12 of the memory cell column R12 that shares the same sub-bit line LBL1 with the memory cell column R11. Hence, no current flows into the memory cell column R12 and the memory cell within the memory cell column R12 would not be programmed. In addition, because no voltage is applied to the gate of the sub-bit line select units BST2 BST4, the main-bit line MBL and the sub-bit line LBL2˜LBL4 are not conducted. Thus, the memory cells in the memory cell columns R21, R31, R32, and R41 would not be programmed.

In the aforementioned programming method, before applying 1.5V to the gate of the sub-bit line select unit BST1 coupled to the memory cell column R11 containing the selected memory cell M12, 6V may be applied to the gate of the sub-bit line select unit BST1. Thereafter, the voltage is lowered from 6V to 1.5V.

In the aforementioned programming method, one of the following two voltage raising methods can be used in the step of applying 1.5V to the selected word line WL13 to increase programming efficiency. In the first method, a voltage smaller than 1.5V (for example, 0.5V) or no voltage (0V) is applied to the word line WL13 first and then the voltage is gradually ramping up to 1.5V. In the second method, a voltage is applied to the word line WL3 in cumulatively until a total voltage of 1.5V is reached. For example, a voltage of 0.3V, 0.6V, 0.9V, 1.2V and 1.5V is sequentially applied. Moreover, at each stage of ramping up the voltage, a program verification step is performed.

In the aforementioned programming method, the programming of the memory cells in a memory cell column preferably starts from the source region side of the memory cell column. For example, the memory cells of the memory cell column R11 are programmed in the order of M11, M12, M13, . . . M1n. In this way, programming interference due to the retention of some electrons in the charge-trapping layers can be avoided so that the programming efficiency is improved.

In the non-volatile memory of the present invention, sub-bit line select units BST1˜BST4 are disposed between the main-bit line MBL and the sub-bit line LBL1˜LBL4. Hence, the sub-bit line select units BST1˜BST4 can be used to control the amount of current flowing from the main-bit line MBL to the sub-bit lines LBL1˜LBL4. In other words, the non-volatile memory has a current-limiting function so that a better programming performance can be achieved.

In the operating method of the present invention, to program data into a selected memory cell, another memory cell adjacent to the selected memory cell and close to the drain region serves as a select unit for injecting electrons into the selected memory cell. For example, the memory cell M13 serves as a select unit in programming the memory cell M12. By applying a lowered voltage to the memory cell M13, electrons are injected into the charge-trapping layer of the selected memory cell M12 on the drain region D side. In the present invention, except that the memory cells M11, M21, M31, M41 which are closest to the source region S serving only as memory cells, all the other memory cells including M12˜M1n, M22 M2n, M32˜M3n, M32˜M3n can serve either as a memory cell or a select unit in a programming operation.

As shown in FIGS. 2 and 3B, to read data from the memory cell Ml 2, for example, 0V is applied to the selected main-bit line MBL and a 1.5V is applied to the non-selected bit lines; 3.3V is applied to the gate of the sub-bit line select unit BST1 coupled to the memory cell column R11 containing the selected memory cell M12 so that the main-bit line MBL and the sub-bit line LBL1 are connected; 1.5V is applied to the word line WL12 coupled to the selected memory cell M12, and 6V is applied to the other non-selected word lines WL11, WL13˜WL1 n and the selected selecting line SG11; and 1.5V is applied to the source line SL1 to read data from the selected memory cell M12. Under such a circumstance, the memory cells with negative-charged charge-trapping layer are turned off and channel current is small, while the memory cells with positive-charged charge-trapping layer are turned on and channel current is large, the on/off state and channel current can be used to determine whether the storage data is ‘1’ or ‘0’.

In the aforementioned reading method, the reading of data from the memory cells of a memory cell column preferably starts sequentially from the source region side of the memory cell column. For example, the memory cells of the memory cell column R11 are read in the order of Ml1, M12, M13, . . . M1n.

As shown in FIGS. 2 and 3C, to perform an erasing operation, 4.5V is applied to the selected main-bit line MBL, and 0V is applied to non-selected main bit lines; 3.3V is applied to the gate of the sub-bit line select unit BST1 coupled to the memory cell column R11 so that the main-bit line MBL and the sub-bit line LBL1 are connected; −5V is applied to the word line WL12 coupled to the selected memory cell M12, and 9V is applied to all the non-selected word lines WL13˜WL1n between the word line WL12 and the drain region D and the selected selecting line SG11; and 0V is applied to all non-selected word lines WL11 between the word line WL12 and the source region S so that holes are injected into the charge-trapping layer to erase the data in the memory cell M12 through hot-hole injection effect.

In the aforementioned operating method, hot-hole injection is used as an example to illustrate the process of erasing data from the memory cell. Obviously, the memory cells can be erased by creating a voltage difference between the gate and the substrate to pull the electrons trapped inside the charge-trapping layer of the memory cell out to the substrate utilizing F-N tunneling effect.

As shown in FIGS. 2 and 3D, the erasing operation is performed by applying 12V to all word lines WL1˜WLn and 0V to the substrate so that a negative gate voltage F-N tunneling effect is produced to erase all the data within the memory cell array.

As shown in FIGS. 2 and 3E, the erasing operation is performed by applying 0V to all the word lines WL1˜WLn and 12V to the substrate (the P-well) so that a F-N tunneling effect is produced to erase all the data within the memory cell array.

As shown in FIGS. 2 and 3F, the erasing operation is performed by applying −6V to all the word lines WL1˜WLn and 6V to the substrate (the P-well) so that a F-N tunneling effect is produced to erase all the data within the memory cell array.

In the aforementioned example of erasing data through the F-N tunneling effect by applying 12V directly to the substrate, an isolation well is preferably formed in the substrate so that the voltage can be directly applied to the well. This prevents the entire wafer from charging up and wasting electric power.

In operating the non-volatile memory of the present invention, source-side injection (SSI) is used to program data into the memory with a single bit of data in a single memory cell serving as a basic unit. Either hot-hole injection or F-N tunneling is used to erase data from the memory cells. Since the electron injection efficiency is high, the operating memory cell current is reduced and the operating speed is increased. Thus, current consumption is minimized and the power loss from the entire chip is effectively reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A non-volatile memory, comprising:
a substrate;
a main-bit line disposed on the substrate;
a sub-bit line select unit;
a sub-bit line connected to the main-bit line through the sub-bit line select unit;
a plurality of word lines arranged in parallel to one another and in a direction perpendicular to the sub-bit line, wherein cross points between the word lines and the sub-bit line constitute a memory cell column;
a column select unit disposed on one side of the memory cell column;
a first doped region disposed in the substrate on one side of the column select unit, wherein the memory cell column is connected to the sub-bit line through the first doped region; and
a second doped region disposed in the substrate on another side of the memory cell column, wherein the memory cell column comprises:
a plurality of first memory cells, wherein each of the first memory cells and the column select unit are isolated from each other by a gap; and
a plurality of second memory cells disposed inside the gaps respectively and serially connected with the first memory cells and the column select unit through a plurality of insulating spacers.

2. The non-volatile memory of claim 1, wherein each first memory cell comprises:
a first gate disposed on the substrate; and
a first composite layer disposed between the first gate and the substrate, wherein the first composite layer comprises a first bottom dielectric layer, a first charge-trapping layer and a top dielectric layer sequentially stacked on the substrate.

3. The non-volatile memory of claim 2, wherein a material constituting the first charge-trapping layer comprises silicon nitride or doped polysilicon.

4. The non-volatile memory of claim 2, wherein a material constituting the first bottom dielectric layer and the first top dielectric layer comprises silicon oxide.

5. The non-volatile memory of claim 2, wherein a material constituting the first gate comprises doped polysilicon.

6. The non-volatile memory of claim 1, wherein each second memory cell comprises:
a second gate disposed on the substrate; and
a second composite layer disposed between the second gate and the substrate and between the second gate and the insulating spacers, wherein the second composite layer comprises a second bottom dielectric layer, a second charge-trapping layer and a second top dielectric layer sequentially.

7. The non-volatile memory of claim 6, wherein a material constituting the second charge-trapping layer comprises silicon nitride or doped polysilicon.

8. The non-volatile memory of claim 6, wherein a material constituting the second bottom dielectric layer and the second top dielectric layer comprises silicon oxide.

9. The non-volatile memory of claim 6, wherein a material constituting the second gate comprises doped polysilicon.

10. The non-volatile memory of claim 1, wherein the column select unit comprises:
a third gate disposed on the substrate; and
a third composite layer disposed between the third gate and the substrate, wherein the third composite layer comprises a third bottom dielectric layer, a third charge-trapping layer and a third top dielectric layer sequentially stacked on the substrate.

11. The non-volatile memory of claim 10, wherein a material constituting the third charge-trapping layer comprises silicon nitride or doped polysilicon.

12. The non-volatile memory of claim 10, wherein a material constituting the third bottom dielectric layer and the third top dielectric layer comprises silicon oxide.

13. The non-volatile memory of claim 10, wherein a material constituting the third gate comprises doped polysilicon.

14. The non-volatile memory of claim 1, wherein the sub-bit line select unit comprises:
a fourth gate disposed on the substrate;
a gate dielectric layer disposed between the fourth gate and the substrate; and
a third doped region and a fourth doped region disposed in the substrate on the each side of the fourth gate respectively, wherein the third doped region connects with the main-bit line and the fourth doped region connects with the sub-bit line.

15. The non-volatile memory of claim 14, wherein a material constituting the gate dielectric layer comprises silicon oxide.

16. The non-volatile memory of claim 14, wherein a material constituting the fourth gate comprises doped polysilicon.

17. The non-volatile memory of claim 1, wherein the memory further comprises a second insulating spacer disposed between the memory cell column and the column select unit.

18. The non-volatile memory of claim 1, wherein the first insulating spacers are formed by depositing an insulating layer on the surface of the first gates and then performing a self-aligned anisotropic etching process.

19. A non-volatile memory, comprising:
a substrate;
a plurality of memory cell columns disposed on the substrate and arranged to form a column/row array, wherein each memory cell column comprises a plurality of serially connected memory cells isolated from each other by a first insulating spacer;
a plurality of column select units disposed on one side of each memory cell column through a second insulating spacer respectively;
a plurality of source regions disposed in the substrate on the other side of the memory cell columns respectively;
a plurality of drain regions disposed in the substrate on the outer side of the column select units respectively, wherein every pair of adjacent memory cell columns in the same column share a common drain region;
a plurality of selecting lines connected to the gates of the column select units in the same row;
a plurality of word lines arranged in parallel in the row direction and connected to the gates of the memory cells in the same row;
a plurality of source lines connected to the source regions in the same row;
a plurality of sub-bit lines connected to the drain regions in the same column such that each sub-bit line serially connects N memory cell columns in the column direction, wherein N is a positive integer;
a plurality of main-bit lines arranged in parallel in the column direction such that each main-bit line connects M sub-bit lines, wherein M is a positive integer, so that each main-bit line serially connects N×M memory cell columns altogether; and
a plurality of sub-bit line select units disposed between the sub-bit lines and the main-bit lines.

20. The non-volatile memory of claim 19, wherein every pair of adjacent memory cells in each memory cell column constitute a memory unit, while one memory cell of each memory unit which is close to the source region serves as a first memory cell and the other which is close to the drain region serves as a second memory cell;
the first memory cell, comprising:
a first gate disposed on the substrate;
a first composite layer disposed between the first gate and the substrate, wherein the composite layer comprises a first bottom dielectric layer, a first charge-trapping layer, and a first top dielectric layer, sequentially stacked on the substrate; and
the second memory cell disposed on a sidewall of the first memory cell, comprising:
a second gate disposed on the substrate; and
a second composite layer disposed between the second gate and the substrate and between the second gate and the first memory cell, wherein the second composite layer comprises a second bottom dielectric layer, a second charge-trapping layer, and a top dielectric layer formed sequentially on the substrate;
wherein the first insulating spacers are disposed on the sidewalls of the first memory cells.

21. The non-volatile memory of claim 20, wherein a material constituting the first charge-trapping layer and the second charge-trapping layer comprises silicon nitride or doped polysilicon.

22. The non-volatile memory of claim 20, wherein a material constituting the first bottom dielectric layer, the first top dielectric layer, the second bottom dielectric layer and the second top dielectric layer comprises silicon oxide.

23. The non-volatile memory of claim 19, wherein each select unit comprises:
a third gate disposed on the substrate;
a third composite layer disposed between the third gate and the substrate, wherein the third composite layer comprises a third bottom dielectric layer, a third charge-trapping layer, and a third top dielectric layer sequentially stacked on the substrate; and
a third insulating spacer, disposed on the third gate and the sidewall of the third composite layer.

24. The non-volatile memory of claim 23, wherein a material constituting the third charge-trapping layer comprises silicon nitride.

25. The non-volatile memory of claim 23, wherein a material constituting the third bottom dielectric layer and the third top dielectric layer comprises silicon oxide.

26. A method of operating a memory cell array, wherein the memory cell array comprises a plurality of memory cell columns disposed on a substrate and arranged to form a column/row array, each memory cell column comprising a plurality of serially connected memory cells without gaps; a plurality of column select units disposed on an outer side of the memory cell columns; a plurality of source regions disposed in the substrate on the other side of the memory cell columns respectively; a plurality of drain regions disposed in the substrate on the outer side of the column select units respectively, wherein every pair of adjacent memory cell columns in the same column share a common drain region; a plurality of selecting lines connected to the gates of the column select units in the same row; a plurality of word lines arranged in parallel in the row direction respectively connected to the gates of the memory cells in the same row; a plurality of source lines connected the source regions in the same row; a plurality of sub-bit lines connected to the drain regions in the same column with each sub-bit line serially connecting N memory cell columns in the column direction, where N is a positive integer; a plurality of main-bit lines arranged in parallel in the column direction with each main-bit line connecting M sub-bit lines, where M is a positive integer and each main-bit line serially connecting N×M memory cell columns; a plurality of sub-bit line select units disposed between the sub-bit lines and the main-bit lines, the method comprising:
performing a programming operation by applying 0V to a selected main-bit line; applying a first voltage to non-selected main-bit lines; applying a second voltage to the gate of the sub-bit line select unit coupled to the memory cell column containing the selected memory cell; applying a third voltage to a selected word line which is adjacent to the word line coupled to the selected memory cell on the drain region side; applying a fourth voltage to other non-selected word lines and selecting lines; and applying a fifth voltage to a selected source line so that source-side injection is triggered to program data into the selected memory cell.

27. The method of claim 26, wherein the first voltage is about 3.3V, the second voltage is about 1.5V, the third voltage is about 1.5V, the fourth voltage is about 9V, and the fifth voltage is about 4.5V.

28. The method of claim 26, wherein before applying the second voltage to the gate of the sub-bit line select unit, the method further comprises a step of applying a sixth voltage to the gate of the sub-bit line select unit first.

29. The method of claim 28, wherein the sixth voltage is about 6V.

30. The method of claim 26, wherein the step of applying the third voltage to the selected word line comprises ramping up the third voltage gradually from about 0V to 1.5V.

31. The method of claim 26, wherein before the step of applying the third voltage to the selected word line, the method further comprises a step of applying a seventh voltage having a value lower than the third voltage to the selected word line first and then ramping up to the third voltage.

32. The method of claim 31, wherein the seventh voltage is about 0.1V.

33. The method of claim 31, wherein a program verification step is performed after each ramping up stage.

34. The method of claim 26, wherein the memory cells are programmed sequentially from the source region side to the drain region side.

35. The method of claim 26, further comprising:
performing a reading operation by applying 0V to the selected main-bit line and an eighth voltage to the non-selected main-bit lines; applying a ninth voltage to the gate of the sub-bit line select unit coupled to the memory cell column containing the selected memory cell; applying a tenth voltage to the word line coupled to the selected memory cell, and applying an eleventh voltage to other non-selected word lines and selected selecting line; and applying a twelfth voltage to the source line to read out the data from the selected memory cell.

36. The method of claim 35, wherein the eighth voltage is about 1.5V, the ninth voltage is about 3.3V, the tenth voltage is about 1.5V, the eleventh voltage is about 6V, and the twelfth voltage is about 1.5V.

37. The method of claim 35, wherein the memory cells are read sequentially from the source region side to the drain region side.

38. The method of claim 26, further comprising:
performing an erasing operation by applying a thirteenth voltage to the selected main-bit line and 0V to the non-selected main-bit lines; applying a fourteenth voltage to the gate of the sub-bit line select unit coupled to the memory cell column containing the selected memory cell; applying a fifteenth voltage to the word line coupled to the selected memory cell, and applying a sixteenth voltage to all the non-selected word lines and selected selecting lines disposed between the word line coupled to the selected memory cell and the drain region; and applying 0V to all the non-selected word lines disposed between the word line coupled to the selected memory cell and the source region so that hot-hole injection is triggered to erase the data from the selected memory cells.

39. The method of claim 38, wherein the thirteenth voltage is about 4.5V, the fourteenth voltage is about 3.3V, the fifteenth voltage is about −5V, and the sixteenth voltage is about 9V.

40. The method of claim 26, further comprising: performing an erasing operation by applying a seventeenth voltage to the word lines and applying a eighteenth voltage to the substrate so that FN tunneling is triggered to erase the data from the entire memory cell array.

41. The method of claim 40, wherein the seventeenth voltage is about −12V and the eighteenth voltage is about 0V.

42. The method of claim 40, wherein the seventeenth voltage is about 0V and the eighteenth voltage is about 12V.

43. The method of claim 40, wherein the seventeenth voltage is about −6V and the eighteenth voltage is about 6V.
